(19) United States
(12) Patent Application Publication
(10) Pub. No.: US 2010/0295172 A1
(43) Pub. Date: Nov. 25, 2010

(54) POWER SEMICONDUCTOR MODULE

(76) Inventors: Shan Gao, Gyunggi-do (KR); Seog Moon Choi, Seoul (KR); Do Jae Yoo, Gyunggi-do (KR); Tae Hyun Kim, Seoul (KR); Bum Sik Jang, Gyunggi-do (KR); Ji Hyun Park, Seoul (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/538,042

(22) Filed: Aug. 7, 2009

(30) Foreign Application Priority Data
May 25, 2009 (KR) 10-2009-0045332

(51) Int. Cl. H01L 23/34

(52) U.S. Cl. 257/712; 257/670; 257/E23.08

(57) ABSTRACT

Disclosed is a power semiconductor module having improved heat dissipation performance, including an anodized metal substrate including a metal plate, an anodized layer formed on a surface of the metal plate, and a circuit layer formed on the anodized layer on the metal plate, a power device connected to the circuit layer, and a housing mounted on the metal plate and for defining a sealing space which accommodates a resin sealing material for sealing the circuit layer and the power device.

### CROSS REFERENCE TO RELATED APPLICATION

This application claims the benefit of Korean Patent Application No. 10-2009-0045332, filed on May 25, 2009, entitled “Power semiconductor module”, which is hereby incorporated by reference in its entirety into this application.

### BACKGROUND OF THE INVENTION

1. Technical Field

The present invention relates to a power semiconductor module.

2. Description of the Related Art

With recent development in electronics used to supply power, electronic products are manufactured to have a small size and a high density. Accordingly, methods not only of reducing the size of an electronic device itself but also of mounting as many devices and wires as possible in a predetermined space are regarded as important when designing semiconductor packages. The density of the semiconductor devices and wiring of the package is increasing more and more, and a large amount of heat is generated in the package. Such heat affects the lifespan and operation of electronic products, and heat dissipation of the high-density package is also an issue.

FIG. 1 is a cross-sectional view showing a conventional power module package. As shown in this drawing, semiconductor devices including a power device 15 and a control device 13 are soldered to the metal surface of a direct copper bonding (DCB) substrate 10 as a circuit board. The DCB substrate 10 functions to electrically insulate the semiconductor devices from a base plate 20 of the module and simultaneously should exhibit thermal conductivity. The base plate 20 and the DCB substrate 10 are electrically insulated from each other using ceramic (Al₂O₃, AlN, SiN, SiC) or an organic material (epoxy, polyimide).

The upper surfaces of the semiconductor devices 13, 15 are connected to a structured region of the metal surface using a thin aluminum wire. Also, passive devices, including a gate resistor and current/temperature sensors, may be integrated in the module, and protective and driving circuit devices and circuits may also be integrated in the module.

Such a conventional power module package is configured such that power devices 15 and diodes are attached to the DCB substrate 10 using solder 17, the DCB substrate is attached to the base plate 20 made of copper to enhance thermal properties using solder 23, and a housing is sealed. For the electrical connection, wedge bonding is applied to between the devices 13, 15 and the substrate 10 and between the substrate 10 and a terminal 27 of the housing. The semiconductor wires 13, 15 and the wires are encapsulated by silicon gel, and a heat dissipation plate 25 is attached to the other surface of the base substrate 20.

However, the conventional power module package thus configured has the following problems.

As the size of the package is reduced, the number of semiconductor devices which must be disposed in the space in the same way is increased, thus generating a large amount of heat in the package. However, because the heat dissipation plate is attached only to the lower surface of the package, heat dissipation does not occur efficiently.

Also, the use of the DCB substrate 10 requires the copper plate 20 which is expensive and large-sized so as to achieve heat dissipation properties. Furthermore, because two bonding processes including the bonding of the semiconductor devices with the DCB substrate and the bonding of the DCB substrate with the base plate should be performed, the manufacturing process becomes complicated. As well, heat dissipation properties are deteriorated attributable to two interface structures including a bonding interface 17 between the semiconductor devices 13, 15 and the DCB substrate 10 and an interface between the DCB substrate 10 and the base plate 20.

### SUMMARY OF THE INVENTION

Accordingly, the present invention has been made keeping in mind the above problems encountered in the related art, and the present invention provides a power semiconductor module having improved heat dissipation performance.

An aspect of the present invention provides a power semiconductor module, which includes an anodized metal substrate including a metal plate, an anodized layer formed on a surface of the metal plate, and a circuit layer formed on the anodized layer on the metal plate, a power device connected to the circuit layer, and a housing mounted on the metal plate and for defining a sealing space which accommodates a resin sealing material for sealing the circuit layer and the power device.

The metal plate may be made of aluminum or an aluminum alloy, and the anodized layer may be an aluminum anodized layer (Al₂O₃).

The power device, and a booth bar disposed on an inner wall of the housing so as to be in contact with a lead frame protruding from the housing, may be connected to the circuit layer using a wire.

Also, the anodized layer may be formed on one surface of the metal plate, and a heat dissipation pin may be formed on the other surface of the metal plate.

Also, a through hole may be formed in the metal plate, the anodized layer may be formed on the surface of the metal plate and on an inner wall of the through hole, and the circuit layer may be formed on the anodized layer on both surfaces of the metal plate, in which a part of the circuit layer formed on the anodized layer on one surface of the metal plate is connected to the other part of the circuit layer on the anodized layer formed on the other surface of the metal plate by a via formed in the through hole.

Another aspect of the present invention provides a power semiconductor module, which includes an anodized metal substrate including a metal plate having a cooler formed therein, an anodized layer formed on a surface of the metal plate, and a circuit layer formed on the anodized layer on the metal plate, a power device connected to the circuit layer, a resin sealing material for sealing the circuit layer and the power device, and a housing mounted on the metal plate and for defining a sealing space which accommodates the resin sealing material.

The cooler may be a heat pipe formed to pass through the metal plate.

The heat pipe may have a coolant flowing therein.

The metal plate may be made of aluminum or an aluminum alloy, and the anodized layer may be an aluminum anodized layer (Al₂O₃).

The power device, and a booth bar disposed on an inner wall of the housing so as to be in contact with a lead frame protruding from the housing, may be connected to the circuit layer using a wire.

A further aspect of the present invention provides a power semiconductor module, which includes an anodized metal substrate including a metal plate having a through hole and a cooler formed therein, an anodized layer formed on a surface of the metal plate and on an inner wall of the through hole, and a circuit layer formed on the anodized layer on both surfaces of the metal plate and connected at the both parts thereof to each other by a via formed in the through hole, a power device connected to the circuit layer, a resin sealing material for sealing the circuit layer and the power device, and a housing mounted on the metal plate and for defining a sealing space which accommodates the resin sealing material.

The cooler may be a heat pipe formed to pass through the metal plate.

The heat pipe may have a coolant flowing therein.

The metal plate may be made of aluminum or an aluminum alloy, and the anodized layer may be an aluminum anodized layer (Al₂O₃).

The power device, and a booth bar disposed on an inner wall of the housing so as to be in contact with a lead frame protruding from the housing, may be connected to the circuit layer using a wire.

The features and advantages of the present invention will be more clearly understood from the following detailed description taken in conjunction with the accompanying drawings.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

### BRIEF DESCRIPTION OF THE DRAWINGS

FIG. 1 is a cross-sectional view showing a conventional power module package;

FIG. 2 is a cross-sectional view showing a power semiconductor module according to a first embodiment of the present invention;

FIG. 3 is a cross-sectional view showing a power semiconductor module according to a second embodiment of the present invention;

FIG. 4 is a cross-sectional view showing a power semiconductor module according to a third embodiment of the present invention;

FIG. 5 is a cross-sectional view showing a power semiconductor module according to a fourth embodiment of the present invention;

FIG. 6 is a cross-sectional view showing a power semiconductor module according to a fifth embodiment of the present invention; and

FIG. 7 is a cross-sectional view showing a power semiconductor module according to a sixth embodiment of the present invention.

### DESCRIPTION OF SPECIFIC EMBODIMENTS

Hereinafter, a detailed description will be given of embodiments of the present invention, with reference to the accompanying drawings. Throughout the drawings, the same reference numerals refer to the same or similar elements, and redundant descriptions are omitted. Also, in the case where known techniques pertaining to the present invention are regarded as unnecessary because they make the characteristics of the invention unclear and also for the sake of description, the detailed description thereof may be omitted.

FIG. 2 is a cross-sectional view showing a power semiconductor module according to a first embodiment of the present invention. Below, the power semiconductor module 100a according to the first embodiment is described with reference to the above drawing.

As shown in FIG. 2, the power semiconductor module 100a according to the first embodiment includes an anodized metal substrate (AMS) 110, a power device 120a, and a housing 130a. In this embodiment, the AMS 110 is used, thereby improving heat dissipation performance of the power semiconductor module 100a.

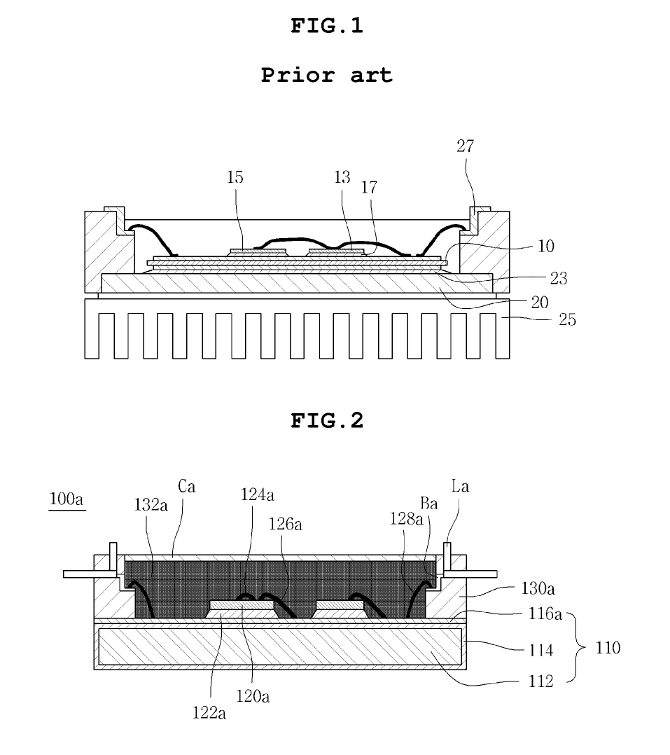

The AMS 110 includes a metal plate 112, an anodized layer 114 formed on a surface of the metal plate 112, and a circuit layer 116a formed on the anodized layer on one surface of the metal plate. The AMS 110 may function as both the base plate 20 and the DCB substrate 10 as seen in FIG. 1.

The metal plate 112 may be made of aluminum (Al) or an aluminum alloy, as examples of metal material which is relatively inexpensive and easily available and exhibits excellent heat transfer properties.

An example of the anodized layer 114 may include an aluminum anodized layer (Al₂O₃) having relatively high heat transfer properties of about 10˜30 W/mK. Specifically, the anodized layer 114 may be formed by immersing the metal plate 112 in an electrolytic solution of boric acid, phosphoric acid, sulfuric acid or chromic acid, and then applying an anode to the metal plate 112 and a cathode to the electrolytic solution. The anodized layer 114 is formed on the surface of the metal plate 112 to thus be responsible for an electrical insulation function, and enables the formation of the circuit layer 116a thereon. Compared to an insulating layer used for the DCB substrate of FIG. 1, the anodized layer 114 is thinner, thus making it possible to manufacture a slim power semiconductor module and also rapidly transferring heat generated from the power device 120a to the metal plate 112, resulting in increased heat dissipation efficiency.

The circuit layer 116a, which is formed on the anodized layer 114 on one surface of the metal plate 112, is connected to the power device 120a by the second wire 126a, and is also connected to a booth bar Ba, which is disposed on the inner wall of the housing 130a so as to be in contact with a lead frame La protruding from the housing 130a, by the third wire 128a, and thereby can communicate with the outside of the housing 130a.

The power device 120a, which is a high-power semiconductor chip, including an insulated gate bipolar transistor, a diode or a control device, is attached to the circuit layer 116a using solder 122a. The power device 120a is interconnected using the first wire 124a, and is connected to the circuit layer 116a using the second wire 126a.

The housing 130a is mounted on the metal plate 112 so as to define a sealing space which accommodates a resin sealing material 132a. The resin sealing material 132a is introduced into the sealing space, thus protecting the circuit layer 116a, the power device 120a and the first to third wires 124a, 126a, 128a from external shock or contamination.

The housing 130a includes the lead frame La which is formed to protrude therefrom and is connected to the circuit layer 116a to provide the driving signal of the power device 120a, and the booth bar Ba which is disposed on the inner wall thereof to be in contact with the lead frame La.

Also, a cover Ca may be mounted to the upper portion of the housing 130a in order to protect the resin sealing material 132a from the outside.

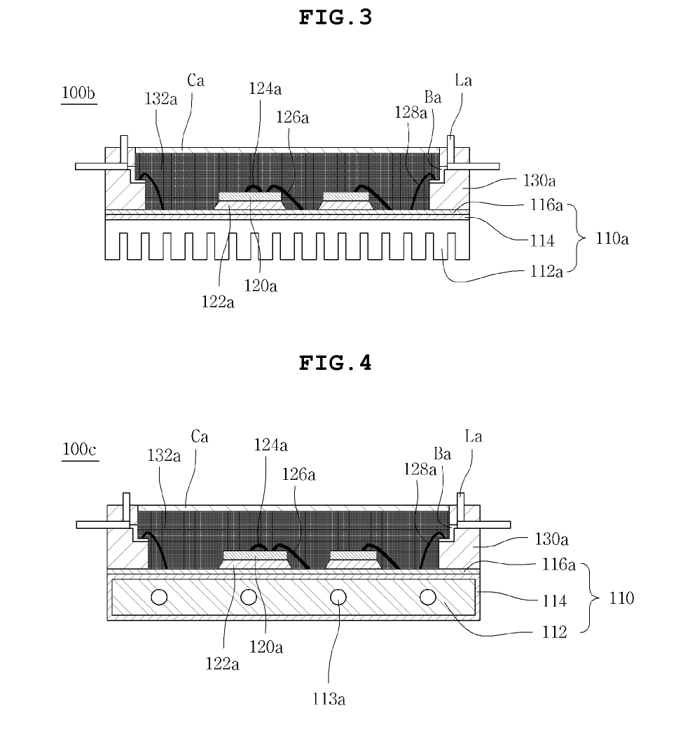

FIG. 3 is a cross-sectional view showing a power semiconductor module according to a second embodiment of the present invention. In the description of the second embodiment, elements which are the same as or similar to those of the first embodiment are designated by the same reference numerals, and redundant descriptions are omitted.

As shown in FIG. 3, the power semiconductor module 100b according to the second embodiment is configured such that the metal plate 112 of the power semiconductor module 100a according to the first embodiment of FIG. 2 has a heat radiation pin 112a. Specifically, the power semiconductor module is formed on one surface of the heat radiation pin 112a, thus increasing the surface area of the heat radiation pin, thereby improving heat radiation performance.

In the second embodiment, because the heat radiation pin 112a is used as a part of the AMS 110a, neither an additional heat radiation plate 25 as seen in FIG. 1 nor an additional member for attaching the heat dissipation plate 25 are required.

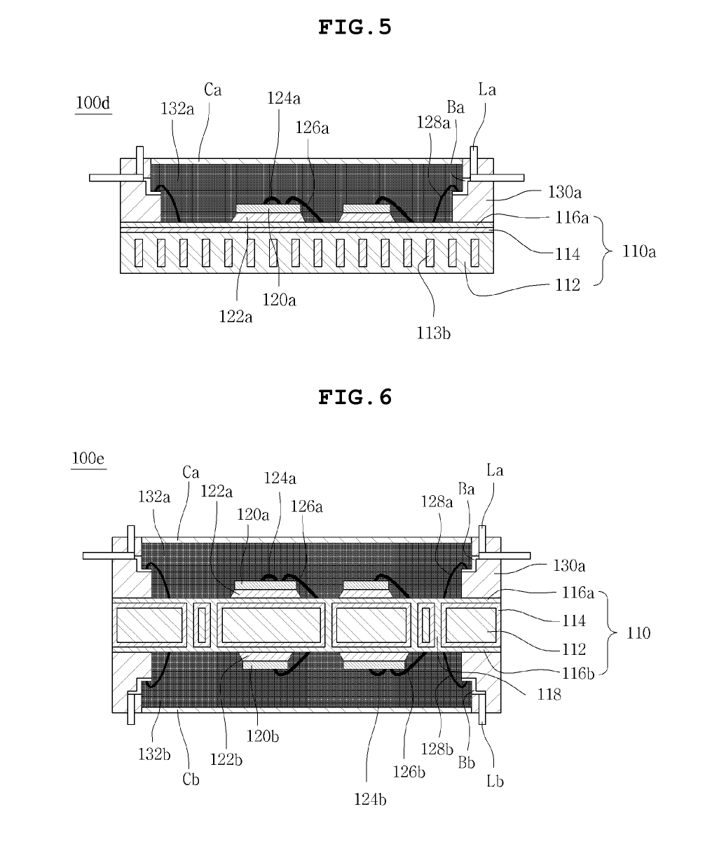

FIGS. 4 and 5 are cross-sectional views showing power semiconductor modules according to third and fourth embodiments of the present invention, respectively. In the description of these embodiments, elements which are the same as or similar to those of the prior embodiments are designated by the same reference numerals, and redundant descriptions are omitted.

As shown in FIGS. 4 and 5, the power semiconductor modules 100c, 100d according to the third and fourth embodiments are configured such that a cooler is provided in a metal plate 112 in order to improve heat dissipation performance.

The cooler may be a heat pipe 113a (the inside of which is in a vacuum) (FIG. 4) formed to pass through the metal plate 112, or a structure (FIG. 5) in which slits for receiving a coolant 113b are formed in the metal plate 112 and the coolant 113b is introduced into the slits thus achieving an additional heat dissipation function. As such, the coolant 113b dissipates heat transferred from the power device 120a and the circuit layer 116a while evaporating and condensing.

Typically, in a power semiconductor module including a high-power semiconductor chip generating much heat upon the operation thereof, the dissipation of generated heat is very important in terms of reliability. In the present embodiments, the cooler is additionally provided, thereby accomplishing additionally improved heat dissipation performance.

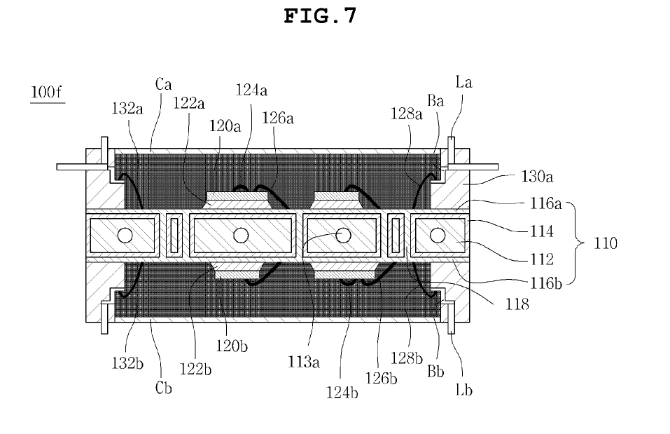

FIG. 6 is a cross-sectional view showing a power semiconductor module according to a fifth embodiment of the present invention. In the description of this embodiment, elements which are the same as or similar to those of the prior embodiments are designated by the same reference numerals, and redundant descriptions are omitted.

As shown in FIG. 6, the power semiconductor module 100e according to the fifth embodiment is configured such that power semiconductor modules are formed on both surfaces of a metal plate 112 (a symmetrical configuration), and are connected to each other using vias 118 formed in the metal plate 112, unlike the power semiconductor module 100a according to the first embodiment.

Specifically, in the power semiconductor module 100e according to the fifth embodiment, an AMS 110 includes a first circuit layer 116a and a second circuit layer 116b respectively formed on upper and lower surfaces thereof, and power devices 120a, 120b and housings 130a, 130b are also respectively mounted on the first circuit layer 116a and the second circuit layer 116b. The first circuit layer 116a and the second circuit layer 116b are connected to each other through the vias 118 formed in the through holes of the metal plate 112.

FIG. 7 is a cross-sectional view showing a power semiconductor module according to a sixth embodiment of the present invention. In the description of this embodiment, elements which are the same as or similar to those of the prior embodiments are designated by the same reference numerals, and redundant descriptions are omitted.

As shown in FIG. 7, the power semiconductor module 100f according to the sixth embodiment is configured such that a cooler such as a heat pipe 113a is formed in the metal plate 112 of the power semiconductor module 100e according to the fifth embodiment, thus improving heat dissipation performance.

Although not shown, the cooler of FIG. 5 may be applied to the metal plate 112.

As described hereinbefore, the present invention provides a power semiconductor module. According to the present invention, the power semiconductor module includes an AMS including an anodized layer in which the number of interfaces is smaller and which is thinner compared to a conventional DCB substrate, thus improving heat dissipation performance. Also, a cooler is additionally provided to a metal plate of the AMS, thus additionally improving heat dissipation performance.

According to the present invention, the use of the AMS which obviates a need for an additional copper plate and is inexpensive compared to the conventional DCB substrate can reduce the manufacturing cost. As well, power semiconductor modules can be formed on upper and lower surfaces of the metal plate, thus obviating a need for an additional heat dissipater.

According to the present invention, there is no need for a copper plate thanks to the use of AMS, and thus the module configuration becomes simple, and also, the power semiconductor module is made slim because of the thin anodized layer.

According to the present invention, because of the symmetrical configuration in which power semiconductor modules are formed on upper and lower surfaces of the metal plate, warping due to stress can be minimized. As well, connection reliability of upper and lower power semiconductor modules can be ensured by a via formed in the metal plate.

Although the embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A power semiconductor module, comprising:
an anodized metal substrate, including a metal plate, an anodized layer formed on a surface of the metal plate, and a circuit layer formed on the anodized layer on the metal plate;
a power device connected to the circuit layer; and
a housing mounted on the metal plate and for defining a sealing space which accommodates a resin sealing material for sealing the circuit layer and the power device.

2. The power semiconductor module according to claim 1, wherein the metal plate comprises aluminum or an aluminum alloy, and the anodized layer is an aluminum anodized layer (Al₂O₃).

3. The power semiconductor module according to claim 1, wherein the power device, and a booth bar disposed on an inner wall of the housing so as to be in contact with a lead frame protruding from the housing, are connected to the circuit layer using a wire.

4. The power semiconductor module according to claim 1, wherein the anodized layer is formed on one surface of the metal plate, and a heat dissipation pin is formed on the other surface of the metal plate.

5. The power semiconductor module according to claim 1, wherein a through hole is formed in the metal plate, the anodized layer is formed on the surface of the metal plate and on an inner wall of the through hole, and the circuit layer is formed on the anodized layer on both surfaces of the metal plate, in which a part of the circuit layer formed on the anodized layer on one surface of the metal plate is connected to the other part of the circuit layer formed on the anodized layer on the other surface of the metal plate by a via formed in the through hole.

6. A power semiconductor module, comprising:
an anodized metal substrate, including a metal plate having a cooler formed therein, an anodized layer formed on a surface of the metal plate, and a circuit layer formed on the anodized layer on the metal plate;
a power device connected to the circuit layer;
a resin sealing material for sealing the circuit layer and the power device; and
a housing mounted on the metal plate and for defining a sealing space which accommodates the resin sealing material.

7. The power semiconductor module according to claim 6, wherein the cooler is a heat pipe formed to pass through the metal plate.

8. The power semiconductor module according to claim 7, wherein the heat pipe has a coolant flowing therein.

9. The power semiconductor module according to claim 6, wherein the metal plate comprises aluminum or an aluminum alloy, and the anodized layer is an aluminum anodized layer (Al₂O₃).

10. The power semiconductor module according to claim 6, wherein the power device, and a booth bar disposed on an inner wall of the housing so as to be in contact with a lead frame protruding from the housing, are connected to the circuit layer using a wire.

11. A power semiconductor module, comprising:
an anodized metal substrate, including a metal plate having a through hole and a cooler formed therein, an anodized layer formed on a surface of the metal plate and on an inner wall of the through hole, and a circuit layer formed on the anodized layer on both surfaces of the metal plate and connected at the both parts thereof to each other by a via formed in the through hole;
a power device connected to the circuit layer;
a resin sealing material for sealing the circuit layer and the power device; and
a housing mounted on the metal plate and for defining a sealing space which accommodates the resin sealing material.

12. The power semiconductor module according to claim 11, wherein the cooler is a heat pipe formed to pass through the metal plate.

13. The power semiconductor module according to claim 12, wherein the heat pipe has a coolant flowing therein.

14. The power semiconductor module according to claim 11, wherein the metal plate comprises aluminum or an aluminum alloy, and the anodized layer is an aluminum anodized layer (Al₂O₃).

15. The power semiconductor module according to claim 11, wherein the power device, and a booth bar disposed on an inner wall of the housing so as to be in contact with a lead frame protruding from the housing, are connected to the circuit layer using a wire.
